(19) United States
(12) Patent Application Publication
(10) Pub. No.: US 2007/0247820 A1
(43) Pub. Date: Oct. 25, 2007

(54) MEMORY MODULE ASSEMBLY INCLUDING HEAT DISSIPATING MEMBERS

(75) Inventors: CHUN-CHI CHEN, TU CHENG (TW); SHI-WEN ZHOU, Shenzhen (CN); ZHAN WU, Shenzhen (CN)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: FOXCONN TECHNOLOGY CO., LTD., TU CHENG (TW)

(21) Appl. No.: 11/308,703

(22) Filed: Apr. 24, 2006

(51) Int. Cl. H05K 7/00

(52) U.S. Cl. 361/729

(57) ABSTRACT

A memory module assembly includes a memory card having a circuit board and a plurality of electronic components mounted on the circuit board. A pair of shells sandwich the memory card therebetween. A first pair of clips sandwich the memory card and the pair of shells therebetween. A fastener extends through the first pair of clips, the pair of shells and the circuit board and holds the first pair of clips toward each other. The first pair of clips each has a pressing portion pressing a corresponding shell of the pair of shells toward the memory card. A second pair of clips each clamps the pair of shells toward the memory card. Thermal tapes thermally connect the electronic components and the shells.

### FIELD OF THE INVENTION

The present invention relates generally to a memory module assembly, and more particularly to a memory module assembly including heat dissipating members for dissipating heat generated by electronic components on a surface of the memory module.

### DESCRIPTION OF RELATED ART

Memory module assemblies that are currently in the use generally do not require cooling devices to dissipate heat. The electronic components and memory module assemblies currently available, which are operated at or below 66 MHz do not generate enough heat to require a cooling device for dissipating the heat. However, as the industry progresses, memory module assemblies such SDRAM DIMM memory module assemblies are required to be operated at 100 MHz and over. For these state-of-the-art memory module assemblies, heat dissipating members will be required to remove generated heat. A locking device such as a clip is also desired in order to secure the heat dissipating members to the electronic components.

What is needed, therefore, is a memory module assembly incorporating a heat dissipating member with great heat dissipating capacity and a clip for easily mounting the heat dissipating member to a surface of the memory module assembly.

### SUMMARY OF INVENTION

A memory module assembly in accordance with a preferred embodiment of the present invention comprises a memory card having a circuit board and a plurality of electronic components mounted on the circuit board. A pair of shells sandwiches the memory card therebetween. A first pair of clips sandwiches the memory card and the pair of shells therebetween. A fastener extends through the first pair of clips, the pair of shells and the circuit board, and then rivets them together. The first pair of clips each comprises a pair of pressing portions which press a corresponding shell of the pair of shells toward the memory card. A second pair of clips each clamps the pair of shells toward the memory card.

Other advantages and novel features will become more apparent from the following detailed description of preferred embodiments when taken in conjunction with the accompanying drawings, in which:

### BRIEF DESCRIPTION OF DRAWINGS

FIG. 1 is an exploded, isometric view of a memory module assembly in accordance with a preferred embodiment of the present invention;

FIG. 2 is an assembled view of FIG. 1; and

FIG. 3 is a view similar to FIG. 2, viewed from a rear aspect.

### DETAILED DESCRIPTION

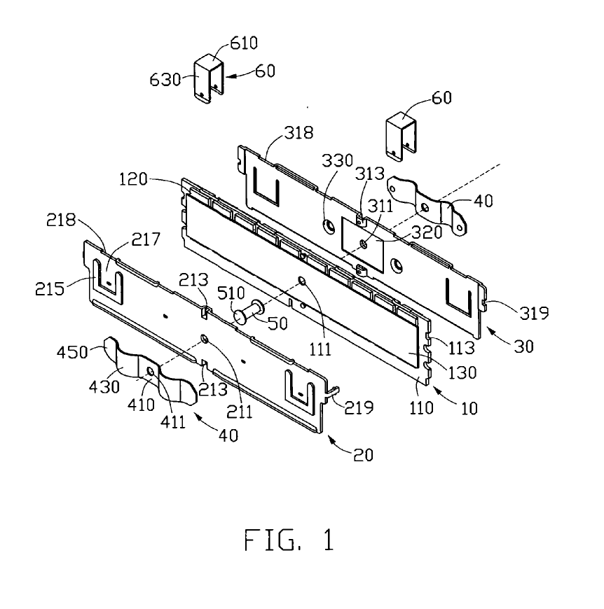

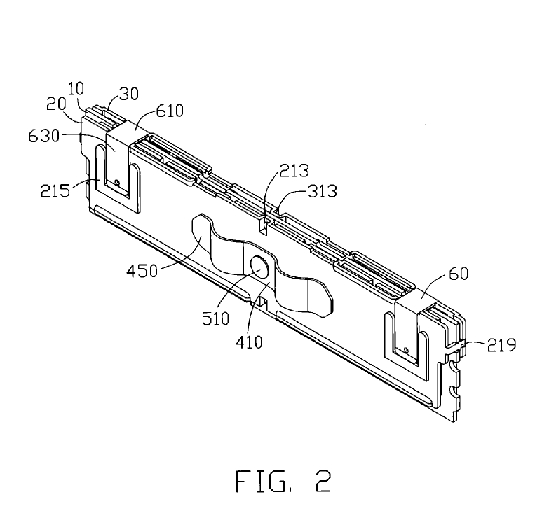

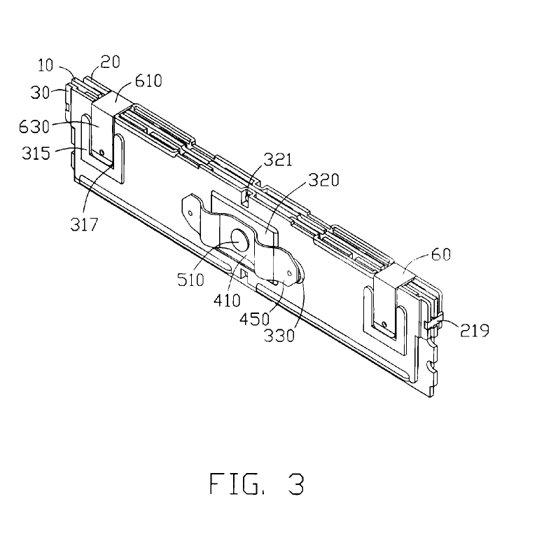

Referring to FIGS. 1-3, a memory module assembly in accordance with a preferred embodiment of the present invention comprises a memory card 10, first and second heat dissipating shells 20, 30 covering two opposite faces of the memory card 10, and a pair of first and a pair of second clips 40, 60 mounting the shells 20, 30 to the memory card 10.

The memory card 10 has a circuit board 110 and a plurality of electronic components 120 mounted on the two faces thereof. A through hole 111 is defined in a center of the circuit board 110. Two gaps 113 are respectively defined in upper portions of two opposite lateral edges of the circuit board 110.

The first, second shells 20, 30 are both manufactured from thermal conductive material such as a metal plate. The first and second shells 20, 30, respectively define two through apertures 211, 311 in centers thereof, aligning with the through hole 111 of the circuit board 110 of the memory card 10. Central areas of lower and upper edges of the first, second shell 20, 30 are stamped to form concave indents extending toward each other, thereby forming fixing portions 213, 313 with through apertures (not labeled) defined therein. Two U-shaped convexes 215, 315 are stamped outwardly adjacent to two ends of the first, second shell 20, 30. Therefore, a pair of positioning portions 217, 317 on the first, second shell 20, 30 are surrounded by the two convexes 215, 315, respectively. The first, second shells 20, 30 have upper edges thereof defining two notches 218, 318 corresponding to the two positioning portions 217, 317. Corresponding to the gaps 113 of the circuit board 110 of the memory card 10, two fixing tabs 219 extend from two lateral edges of the first shell 20 toward the second shell 30. Each tab 219 forms upper and lower barbs (not labeled) adjacent to a distal end thereof. The second shell 30 defines two cutouts 319 corresponding to the gaps 113 of the circuit board 110 and the tabs 219 of the first shell 20.

In order to ensure that the shells 20, 30 have good thermal contact with the electronic components 120 on the circuit board 110 of the memory card 10, thermal tapes 130 are sandwiched between the shells 20, 30 and the memory card 10. The tapes 130 have good thermal conductivity, and cover the electronic components 120 on the circuit board 110. The thermal tape 130 attached to a corresponding face of the memory card 10 can be a single piece, or can be divided into pieces. In this preferred embodiment, the tape 13 between the first shell 20 and the memory card 10 is a single piece, while the tape 130 between the second shell 30 and the memory card 10 is divided to two pieces, because the electronic components 120 on a rear face of the circuit board 110 as viewed from FIG. 1 are divided into to two separate groups with each group being covered with one of the two pieces of the thermal tape 13. Another electronic component (not shown) is located at a center of the rear face of the circuit board 110 between the two groups of electronic components 120. The another electronic component has a raised height. The second shell 30 is stamped outwardly in a substantially central portion thereof to form a receiving portion 320 to accommodate the another electronic component. In this case, the through aperture 311 is substantially in a center of the receiving portion 320 and the second shell 30 is stamped outwardly to form two protrusions 330 at two opposite sides of the receiving portion 320.

Each of the pair of first clips 40 is integrally formed by bending a length of metal, and comprises an engaging portion 410, two arc-shaped flexible portions 430 extending from two lateral sides of the engaging portion 410, and two pressing portions 450 extending from their respective ends of the two flexible portions 430. A fastening hole 411 is defined in a center of the engaging portion 410.

Each second clip 60 is substantially inverted U-shaped, and comprises a main body 610 and two clamping boards 630 descending from two opposite edges of the main body 610. The two clamping boards 630 define two fastening apertures (not labeled) adjacent to distal ends thereof.

In assembly, the tabs 219 of the first shell 20 are fitted in the gaps 113 of the circuit board 110 of the memory card 10 and the cutouts 319 of the second shell 30. The distal ends of the tabs 219 are deformed to abut against the second shell 30 toward the memory card 10. The barbs abut against the circuit board 110 of the memory card 10 toward the first shell 20. Additionally, the first, second shells 20, 30 and the circuit board 110 are locked together via two bolts 321 connecting the fixing portions 213, 313 of the first, second shells 20, 30 and the circuit board 110 together. Therefore, the first, second shells 20, 30 and the memory card 10 are preassembled together with the tapes 130 being sandwiched between the first, second shells 20, 30 and the memory card 10. The pair of first clips 40 sandwiches the first shell 20, the tape 130 the memory card 10 and the second shell 30 therebetween. A fastener 50 extends through the first shell 20, the tape 130, the memory card 10 and the second shell 30, by fitting in the fastening holes 411, the through aperture 211 of the first shell 20, the through hole 111 of the circuit board 110 of the memory card 10 and the through aperture 311 of the second shell 30. Two ends of the fastener 50 which project beyond the fastening holes 411 of the two first clips 40 are expanded to form two abutting portions 510 abutting against the engaging portions 410 of the first clips 40 to press the two first clips 40 toward each other. A rear one of the first clips 40 is further fixed to the second shell 30 via screws (not shown) extending through the pressing portions 450 of the rear one of the first clips 40 and screwing in the protrusions 330 of the second shell 30. The second clips 60 clamp the first and second shells 20, 30 toward each other via the clamping boards 630 thereof abutting against the positioning portions 217, 317 of the first and second shells 20, 30. Furthermore, the clamping boards 630 are fixed to the first and second shells 20, 30 by a plurality of screws (not shown). Therefore, the first shell 20, the memory card 10 and the second shell 30 are firmly assembled together, and the thermal tapes 130 thermally connect the electronic components 120 and the shells 20, 30 together, whereby heat generated by the electronic components 120 is transmitted to the shells 20, 30 and dissipated to surrounding air.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A memory module assembly comprising:
a memory card having a circuit board and a plurality of electronic components located on the circuit board;
a pair of shells sandwiching the memory card therebetween; and a pair of clips sandwiching the memory card and the pair of shells therebetween, a fastener extending through the pair of clips, the pair of shells and the circuit board, the fastener holding the pair of clips together, the pair of clips each comprising a pressing portion pressing a corresponding shell of the pair of shells toward the memory card.

2. The memory module assembly of claim 1, wherein the pair of shells each has top and bottom edges fixed to the circuit board of the memory card.

3. The memory module assembly of claim 2, wherein each of the top and bottom edges of each of the pair of shells is stamped toward the circuit board of the memory card to form a fixing portion, with fasteners fastening the fixing portions and the circuit board together.

4. The memory module assembly of claim 1, wherein the pair of clips each comprises an engaging portion having the fastener extending therethrough and abutting thereagainst, the pressing portion of each of the pair of clips extending from the engaging portion.

5. The memory module assembly of claim 4, wherein the pair of clips each is integrally formed from a length of material, and further comprises two flexible portions extending from opposite sides of the engaging portion thereof and a second pressing portion pressing the corresponding shell of the pair of shells toward the memory card, with each of the two pressing portions extending from a corresponding flexible portion.

6. The memory module assembly of claim 5, wherein the two pressing portions of one of the pair of clips are fixed to one of the pair of shells.

7. The memory module assembly of claim 1 further comprising a pair of second clips each nipping the pair of shells toward the memory card.

8. The memory module assembly of claim 7, where the pair of second clips each comprises a main body and two clamping boards extending in a same direction perpendicularly from opposite ends of the main body to press the pair of shells toward the memory card.

9. The memory module assembly of claim 8, wherein the pair of shells each is stamped outwardly to form two substantially convex indents adjacent to two opposite lateral sides thereof, the clamping boards of the pair of second clips being surrounded by corresponding convexes.

10. The memory module assembly of claim 9, wherein the clamping boards of the pair of second clips are fixed to the pair of shells.

11. The memory module assembly of claim 1 further comprising thermal medium sandwiched between the pair of shells and the memory card and thermally connecting the electronic components with the pair of shells.

12. A memory module assembly comprising:
a memory card comprising a circuit board and a plurality of electronic components mounted on the circuit board;
a pair of shells sandwiching the memory card therebetween, the pair of shells covering two faces of the memory card;
a first pair of clips sandwiching the memory card and the pair of shells therebetween; and
a second pair of clips each clamping the pair of shells toward the memory card.

13. The memory module assembly of claim 12, wherein the first pair of clips are located in substantially central areas of the pair of shells, and each integrally comprises an engaging portion, two flexible portions oppositely extending from two sides of the engaging portion, and two pressing portions formed at distal ends of the flexible portions, the pressing portions pressing the pair of shells toward the circuit board.

14. The memory module assembly of claim 13, wherein a fastener extends through the engaging portions of the first pair of clips, the pair of the shells and the circuit board of the memory card, and has two ends thereof abutting against the first pair of clips toward each other.

15. The memory module assembly of claim 12, wherein the second pair of clips are located adjacent to two ends of the pair of shells, each comprises a pair of clamping boards pressing the pair of shells toward the memory card, and a main body connecting the pair of clamping boards.

16. The memory module assembly of claim 12 further comprising thermal medium sandwiched between the pair of shells and the memory card and thermally connecting the electronic components and the shells.

17. The memory module assembly of claim 16, wherein the thermal medium is a thermal tape.

18. A memory module assembly comprising:
a circuit board;
a plurality of electronic components mounted on two opposite faces of the circuit board;
a pair of metal shells covering the two opposite faces of the circuit board;
thermal medium thermally connecting the electronic components and the shells;
a first pair of clips resilient abutting against the metal shells, respectively, and pushing the shells toward the circuit board; and
a fastener extending through the first pair of clips, the shells and the circuit board to connect them together.

19. The memory module of claim 18 further comprising a substantially U-shaped second clip clamping the shells toward the circuit board.

20. The memory module of claim 19, wherein each of the first pair of clip having a central engaging portion engaging with a corresponding shell, a pair of arc resilient portions extending from two sides of the engaging portion and a pair of pressing portions extending from the resilient portions, respectively, and abutting against the corresponding shell toward the circuit board.
